(19) United States
(12) Patent Application Publication
(10) Pub. No.: US 2016/0343842 A1
(43) Pub. Date: Nov. 24, 2016

(54) METHOD OF GROWING AN EPITAXIAL SUBSTRATE AND FORMING A SEMICONDUCTOR DEVICE ON THE EPITAXIAL SUBSTRATE

(71) Applicant: SUMITOMO ELECTRIC DEVICE INNOVATIONS, INC., Yokohama-shi (JP)

(72) Inventor: Hajime MATSUDA, Yokohama-shi (JP)

(73) Assignee: SUMITOMO ELECTRIC DEVICE INNOVATIONS, INC., Yokohama-shi (JP)

(21) Appl. No.: 15/160,060

(22) Filed: May 20, 2016

(30) Foreign Application Priority Data
May 20, 2015 (JP) 2015-102840

(51) Int. Cl. H01L 29/778; H01L 21/02; H01L 29/66; H01L 29/20; H01L 29/205

(52) U.S. Cl. CPC H01L 29/7787; H01L 29/2003; H01L 29/205; H01L 29/66462; H01L 21/02458; H01L 21/0254; H01L 21/02584; H01L 21/02645

(57) ABSTRACT

A process of forming an epitaxial substrate for a high electron mobility transistor (HEMT) is disclosed. The process includes a sequential growth of a buffer layer, a barrier layer, and a cap layer, where those layers are made of nitride semiconductor materials. A feature of the process is that nitrogen (N₂) is added to a source material for the group V element. Preferably, the process supplies the nitrogen (N₂) within. the reaction chamber through a supply line common to the source material for the group V element.

### BACKGROUND OF THE INVENTION

1. Filed of the Invention

The present application relates to a method of growing an epitaxial substrate and forming a semiconductor device on the epitaxial substrate.

2. Background Arts

Various processes have been reported regarding to an epitaxial substrate applicable to an electrical device made of nitride semiconductor materials. Japanese Patent Application laid open No 2011-023677A has disclosed a method including steps of sequentially growing a seed layer made of aluminum nitride (AlN) on a substrate made of silicon carbide (SiC), a buffer layer made of gallium nitride (GaN) on the AlN seed layer, a channel layer made of GaN on the GaN buffer layer, and a barrier layer made of aluminum-gallium-nitride (AlGaN) on the GaN channel layer, where the growth of those layers of the AlN layer, the GaN buffer layer, the GaN channel layer, and the AlGaN barrier layer are carried out as supplying ammonia (NH₃) as a source material for a group V element, namely, the nitrogen (N). When an electron device formed on an epitaxial substrate thus prepared, surface pits appearing in a grown surface are preferably as few as possible because the surface pits degrade electrical performance of the device.

### SUMMARY

One aspect of the present invention relates to a process of forming an epitaxial substrate made of nitride semiconductor materials, The process comprises steps of: (a) growing a buffer layer made of nitride semiconductor material on a substrate by a metal organized chemical vapor deposition (MOCVD) technique as supplying ammonia (NH₃) as a source material for nitrogen (N); and (b) growing a barrier layer made of nitride semiconductor material on the buffer layer. A feature of the process of the present invention is that the step of growing the buffer layer includes a step of supplying a nitrogen gas (N₂) with the ammonia (NH₃). The buffer layer may be grown at a temperature higher than 1000° C. Also, the MOCVD technique provides a reaction chamber within which the epitaxial substrate subject to the present invention is processed. The reaction chamber provides a supply line for supplying the ammonia (NH₃) within the reaction chamber. The feature of the present invention is that the nitrogen gas (N₂) is also supplied within the reaction chamber through the supply line for the ammonia (NH₃).

Another aspect of the present invention relates to a method to form a high electron mobility transistor (HEMT). The method includes steps of: forming an epitaxial substrate by sequentially growing on a seed layer, a buffer layer, and a barrier layer on a substrate by a metal organic chemical vapor deposition (MOCVD) technique, where these layers of the seed layer, the buffer layer, and the barrier layer are made of nitride semiconductor materials; and forming electrodes of a gate, a source, and a drain on the epitaxial substrate. A feature of the method of the present invention is that, at least the step of growing the buffer layer includes a step of supplying ammonia (NH₃) within a reaction chamber of the MOCVD technique mixed with a nitrogen gas (N₂).

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 shows a cross section of an epitaxial substrate prepared by a process according to an embodiment of the present invention;

FIG. 2 shows a cross section of an electrical device type of a high electron mobility transistor (HEMT) formed on the semiconductor substrate shown in FIG. 1;

FIG. 3 is a flow chart of a process for forming the electrical device shown in FIG. 2;

FIG. 4A shows a relation of a growth rate against a growth temperature of a GaN layer, and FIG. 4B shows a relation of a pit density against a growth rate of the GaN layer;

FIG. 5 shows a relation of a growth rate against a leak current of the electrical device shown in FIGS. 2 and 3; and

FIG. 6 shows a cross section of another electrical device whose arrangement is modified from that of the electrical device shown in FIG. 1.

### DETAILED DESCRIPTION

### Explanation of an Embodiment of the Present Invention

Next, embodiment of the present invention will be described in detail. In the explanation of drawings, numerals or symbols same with or similar to each other will refer to elements same with or similar to each other without duplicating explanations.

### First Embodiment

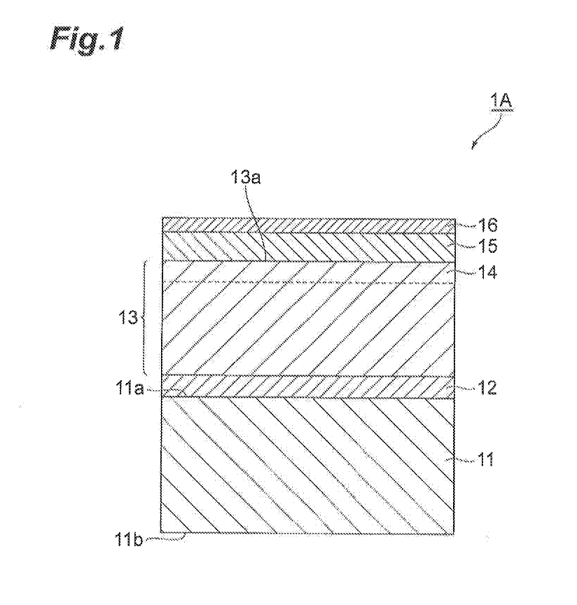

FIG. 1 shows a cross section of an epitaxial substrate prepared by a method according to the first embodiment of the present invention. The epitaxial substrate 1A, which is preferably applicable to, for instance, a high electron mobility transistor (HEMT), includes a substrate 11, a seed layer 12, a buffer layer 13, a barrier layer 15, and a cap layer 16.

The substrate 11, which may be made of silicon carbide (SIC), silicon (Si), and sapphire (Al₂O₃), has a top surface 11a and a back surface 11b, where layers, 12 to 16, are sequentially formed on the top surface 11a of the substrate 11. The substrate 11 of the present embodiment is made of SiC. The seed layer 12 may enhance quality, typically crystallinity, of semiconductor layers to be grown thereon. The seed layer 12 of the present embodiment is made of undoped AlN with a thickness of 10 to 50 nm, generally around 15 nm.

The buffer layer 13, which is epitaxially grown on the seed layer 12, may be made of nitride semiconductor materials, where the present embodiment provides an undoped GaN layer as the buffer layer 13. The buffer layer 13 has a thickness of 0.5 to 2.0 μm, typically around 1.0 μm. When the epitaxial substrate 1A is to be formed in a HEMT, the buffer layer 13 may provide a channel 14 in a vicinity of the top surface 13a thereof, where the channel 14 includes two-dimensional electron gas (2DEG) in the interface between the buffer layer 13 and the barrier layer 15.

The barrier layer 15, which is epitaxially grown on a top surface 13a of the buffer layer 13, may be made of undoped AlGaN having aluminum (Al) composition of 0.2 with respect to gallium (Ga). The AlGaNT barrier layer may have a thickness of 10 to 50 nm. The cap layer 16, which may protect the semiconductor layers, 12 to 15, thereunder, may be made of undoped GaN with a thickness of 2 to 10 nm, preferably 5 nm.

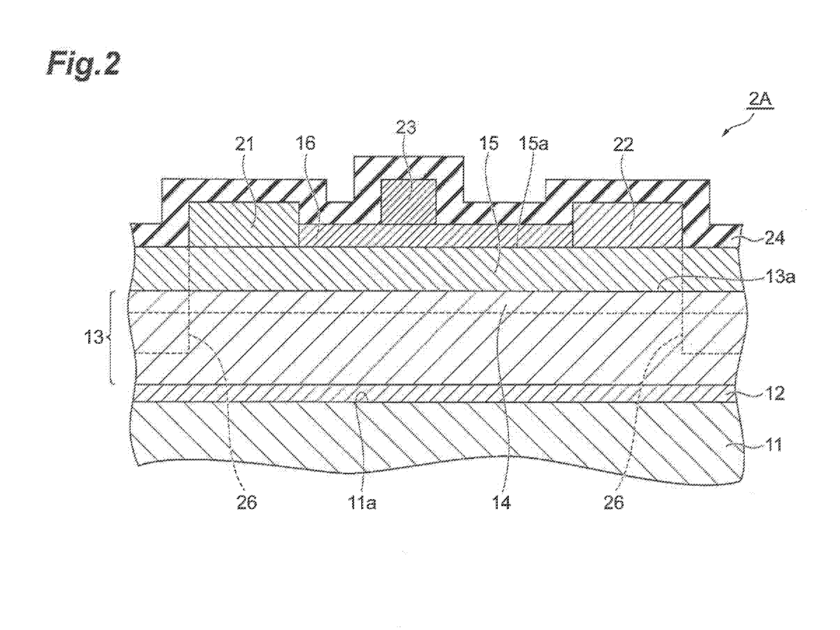

FIG. 2 shows a cross section of a HEMT 2A formed from the epitaxial substrate 1A described above. As shown in FIG. 2, the HEMT 2A includes, in addition to the epitaxial substrate 1A, a source electrode 21, a drain electrode 22, a gate electrode 23, and a passivation layer 24. The source electrode 21 and the drain electrode 22, where they are directly in contact to a top surface 15a. of the barrier layer 15 by partly removing the cap layer 16 and the passivation layer 24. The source electrode 21 and the drain electrode 22 may be made of a metal stack of titanium (Ti) and aluminum (Al) and show a non-rectifier characteristic, namely, an ohmic characteristic against the barrier layer 15. In the present embodiment, the source electrode 21 and the drain electrode 22 have a stacked structure of the titanium (Ti) and the aluminum (Al), but those electrodes, 21 and 22, may further provide other titanium (Ti) layers on respective aluminum (Al) layers. That is, the aluminum (Al) layer may be sandwiched by the titanium (Ti) layers.

The gate electrode 23, which is provided on the cap layer 16 between the source and drain electrodes, 21 and 22, may be made of another stacked metal of nickel (Ni) and gold (Au), where the nickel (Ni) is in contact to the cap layer 16. In the embodiment shown in FIG. 2, the gate electrode 23 is provided on the cap layer 16, but the gate electrode 23 may be directly in contact to the barrier layer 15 by partly removing the cap layer 16.

The passivation layer 24, which cover the source, drain, and gate electrodes, 21 to 23, may be made of silicon nitride (SiN). The HEMT 2A may further provide isolation regions 26 in respective outer sides of the source electrode 21 and the drain electrode 22. The isolation regions 26 may be formed by, for instance, implanting argon (Ar) ions therein,

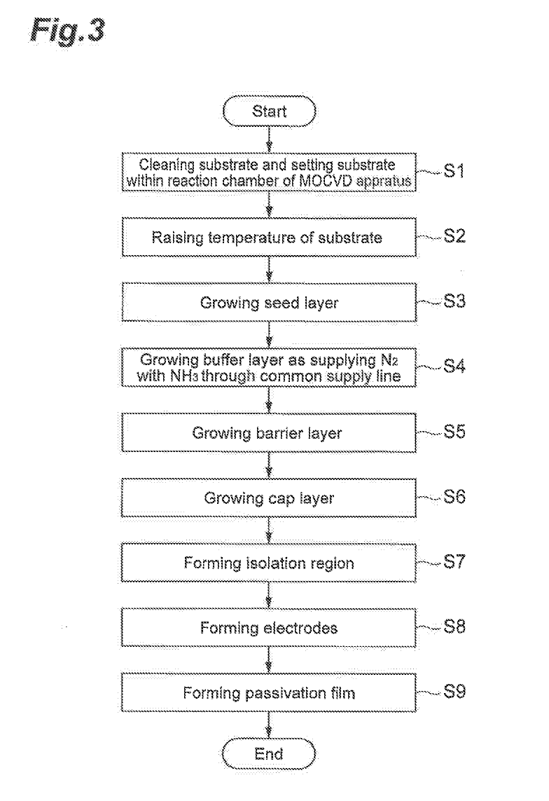

Next, a process to form the epitaxial substrate 1A and the HEMT 2A will be described according to a flow chart shown in FIG. 3. In the present process, the seed layer 12, the buffer layer 13, the barrier layer 15, and the cap layer 16 may be formed by the metal organized chemical vapor deposition (MOCVD) technique which is conventionally adopted for growing various semiconductor layers.

The process first rinses a substrate 11 by chemicals, then sets thus rinsed substrate 11 on a stage in a reaction chamber of the MOCVD apparatus at step Si. Then, a temperature of the substrate 11 is raised to 1140° C. as keeping a pressure within the reaction chamber to be 100 Torr (13.3 kPa). The substrate is held at this temperature, 1140° C., for 20 minutes as supplying hydrogen (H₂) within the reaction chamber, at step S2.

Then, at step S3, dropping the temperature of the substrate 11 to, for instance 1100° C., the process supplies tri-methyl-aluminum (TMA) accompanied with a carrier gas into the reaction chamber as a source material for the group III element concurrently with ammonia (NH₃) as a source material for the group V element. The carrier gas may be hydrogen (H₂). Thus, the seed layer 12 is grown on the substrate 11. In this step S3, nitrogen (N₂) in a quite small amount may be contained in a supply line of the ammonia (NH₃) for the reaction chamber.

Next, at step S4, the process supplies tri-methyl-gallium (TMG) as a source material for the group III element accompanied with the carrier gas into the reaction chamber concurrently with the ammonia (NH₃) as the source material for group V element. The carrier gas may be also hydrogen (H₂). Thus, the GaN buffer layer 13 may be grown on the AlN seed layer 12. In step S4, the temperature of the substrate 11 and flow rates of the source materials may be adjusted such that the growth rate of the GaN buffer layer 13 becomes, for instance, 240 pm/sec. Also, the supply of the ammonia (NH₃) may accompany with a faint amount of the nitrogen (N₂); that is, the nitrogen (N₂) may be contained in the supply line for ammonia (NH₃) by a faint amount. An example of the growth condition of the GaN buffer layer 13 is that; the temperature of the substrate, the flow rate of the TMG that of the ammonia (NH₃), the pressure in the reaction chamber are 1060° C., 53 sccm, 20 slm and 100 Torr (13.3 kPa), respectively. Also, a ratio of the nitrogen (N₂) against the ammonia (NH₃), where they are supplied through the common supply line, may be 1.0 to 100 ppm, preferably around 40 ppm.

Next, the AlGaN barrier layer 15 may be grown at step S5 by supplying a mixture of the TMG and the TMA with a carrier gas as the source materials for the group III elements within the reaction chamber concurrently with the supply of the ammonia (NH₃) as the source material for the group V element. During the growth of the AlGaN barrier layer 15, the substrate 11 may be kept in the temperature thereof same with that during step S4, during which the GaN barrier layer 14 is grown. That is, the temperature of the substrate 11 may be kept in 1060° C. during steps S4 and S5. Also at the step S5, the supply line for the ammonia (NH₃) may contain a faint amount of the nitrogen (N₂). For instance, the ratio of the nitrogen (N₂) against the ammonia (NH₃) may be kept in 10 to 100 ppm, preferably around 40 ppm.

Next at step S6, the process supplies the TMG as a source material for the group III element with the carrier gas within the reaction chamber concurrently with the ammonia (NH₃) as the source material for the group V element as keeping the temperature of the substrate 11 to be 1060° C., which is same with the temperatures during steps S4 and S5. Thus, the GaN cap layer 16 may be grown on the AlGaN harrier layer 15. Also in step S6, a faint amount of nitrogen (N₂) may be contained in the supply line for the ammonia (NH₃) by a ratio against ammonia (NH₃) same with that in the previous steps, S4 and S5.

Thus, the epitaxial substrate 1A may be prepared by steps, S1 to S6. Next, a process of forming the HEMT 2A subsequent to the step S6 will be described. At step S7, an isolation region 26 is first formed. Specifically, partially removing the cap layer 16 so as to leave a portion covering an active region surrounded by the isolation region 26, and subsequent implantation of, for instance, argon ions (Ar⁺) by a depth reaching the GaN bather layer 13; the active region is surrounded by the isolation region 26 and electrically isolated from neighbor active regions. Then at step S8, the source and drain electrodes, 21 and 22, are formed by partially removing the cap layer 15 so as to leave a portion beneath the gate electrode 23; and the gate electrode 23 is formed on a rest portion of the cap layer 16. Subsequent step S9 may form a passivation layer 24 that covers or passivates the respective electrodes, 22 to 24, and the isolation region 26 surrounding the active region. Thus, the process of forming the HMT 2A is completed.

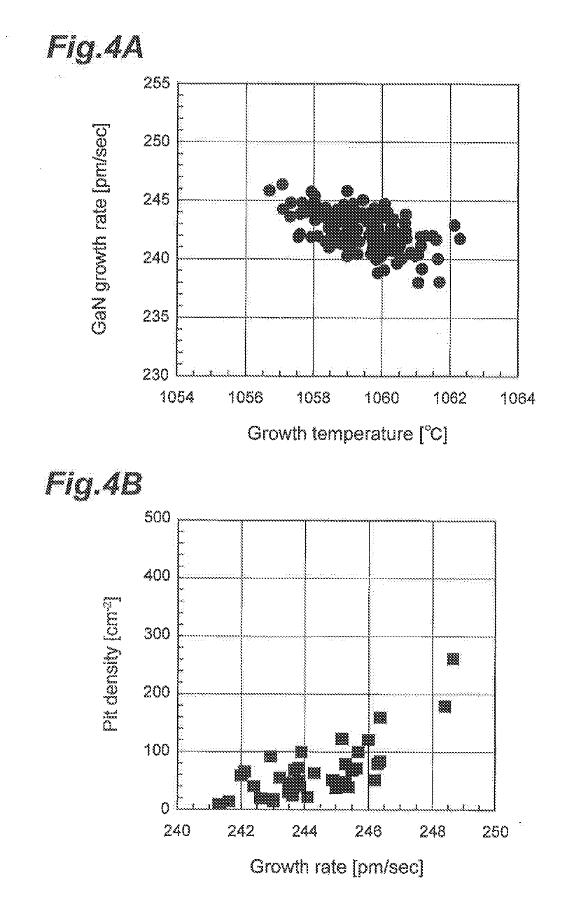

The epitaxial growth of the nitride semiconductor layers, in particular, the growth rate of the nitride semiconductor materials depends on the deposition of the materials by the reaction of the source materials and the sublimation of the deposited materials. FIG. 4A shows various relations between the growth temperature (CC) and the growth rate (pm/sec) of GaN layers. As shown in FIG. 4A, the sublimation of the deposited materials increases and the growth rate decreases as raising the growth temperature. On the other hand, lowering the growth temperature, the growth rate increases because of the deposition of the materials dominates.

However, a higher growth rate inevitably accompanies with the degradation of the quality of a grown layer because compensation of defects caused during the epitaxial growth becomes hard, which results in an increase of defects, which is verified by the etch-pit density, of the surface of the grown layer. FIG. 4B plots a relation between the growth rate (pm/sec) and the etch-pit density (cm⁻²) of the epitaxial GaN layers. FIG. 4B clearly shows that the etch-pit density increases as the growth rate increases. Accordingly, in order to decrease the etch-pit density, the growth temperature is preferably higher to slow the growth rate.

However, defects caused by the dissociation of gallium (Ga) and nitrogen (N₂), especially, that of the nitrogen (N₂) by the vaporization thereof increase as raising the growth temperature to enhance the sublimation, which disarranges the stoichiometry in the surface and increases acceptors primarily due to vacancies of nitrogen atoms (N) and a leak current of the HEMT 2A.

On the other hand, the process of preparing the epitaxial substrate 1A and forming the HEMT 2A in the epitaxial substrate 1A grows the nitride semiconductor layers by the MOCVD technique using the ammonia (NH₃) as the source material, for the group V element that contains the nitrogen (N₂) to enhance a partial pressure of the nitrogen (N₂), which effectively suppresses the sublimation of the nitrogen atoms from the surface of the grown layers. Accordingly, the etch-pit density induced on the surface of the grown layers may be suppressed and the leak current may be reduced.

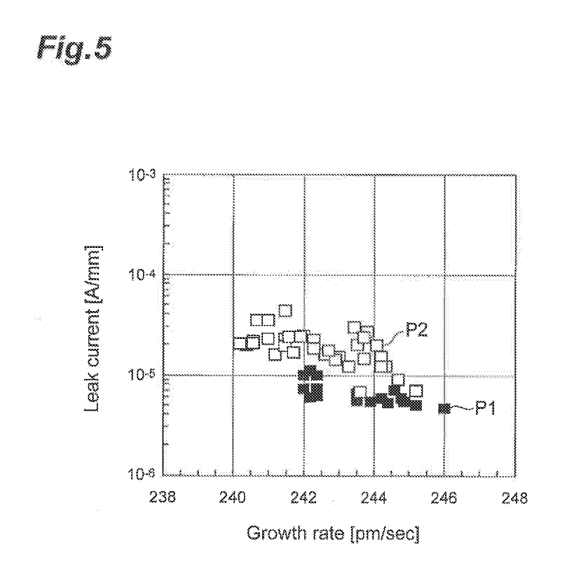

FIG. 5 shows the relation of the leak current [A/mm] with respect to the growth rate [pm/sec] of the GaN layer, where the results P1 correspond to a condition of the present invention where the nitrogen (N₂) is added in the ammonia (NH₃), while the results P2 correspond to another condition where the supply line of the ammonia (NH₃) contains no nitrogen (N₂). In the results P2 comparable to the present embodiment, the leak current increases as slowing the growth rate. While, the results P1 of the present embodiment shows a moderate tendency of the leak current against the growth rate. Thus, the process of the present invention, specifically, the addition of the nitrogen (N₂) to the source material for the group V element, namely the ammonia (NH₃), may reduce the etch-pit density consistent with the reduction of the leak current. The process of the embodiment may reduce the etch-pit density less than 100 cm⁻².

The nitrogen (N₂) is preferably supplied through a supply line of the MOCVD apparatus common to the ammonia (NH₃) to make the partial pressure of the nitrogen (N₂) uniform on a whole surface of the substrate 11. The ratio of the nitrogen (N₂) against the ammonia (NH₃) may be 10 to 100 ppm, preferably around 40 ppm. Such a faint amount of the nitrogen (N₂) may effectively suppress the sublimation of the nitrogen atoms (N) from the surface of the grown layer and maintain the crystal quality of the grown layer.

The step of growing the barrier layer 15 may also add the nitrogen (N₂) to the ammonia (NH₃). The addition of the nitrogen (N₂), similar to the process of growing the GaN buffer layer 14, may effectively reduce the etch-pit density appearing on the surface of the GaN buffer layer 14 without increasing the leak current. Moreover, the step of growing the cap layer 16 may also add the nitrogen (N₂) to the ammonia (NH₃). The etch-pit density caused in the surface of the cap layer 16 may be effectively reduced without increasing the leak current. The process of forming the epitaxial substrate 1A may adopt the hydrogen (H₂) as the carrier gas of the source material for the group III elements at the steps of growing the buffer layer 13, the barrier layer 15, and the cap layer 16. The hydrogen (H₂) may be clearly distinctive from the nitrogen (N₂); the advantages to add the nitrogen (N₂) to the ammonia (NH₃) may become conspicuous.

In the present embodiment of the epitaxial substrate 1A and the HEMT 2A, a thickness of the buffer layer 13, for instance around 1 μm, is greater than that of the barrier layer 15 and the cap layer 16, where that latter two layers have respective thickness of several nano-meters. Accordingly, the leak current subject to the investigation of the present invention primarily occurs in the buffer layer 13. The steps of growing the barrier layer 15 and the cap layer 16 may omit the addition of the nitrogen (N₂) in the supply line of the ammonia (NH₃).

[First Modification]

The embodiment of growing the barrier layer 15 and the cap layer 16 thus described adds the nitrogen (N₂) in the supply line of the ammonia (NH₃). The process of growing those layers, 15 and 16, may add source materials for donors instead of the nitrogen (N₂). That is, the process of growing the barrier layer 15 and the cap layer 16 supply materials for the n-type dopant, for instance slime (SiH₄) in the reaction chamber of the MOCVD apparatus. The n-type dopant in a flow rate thereof is set such that the doping density of the grown layer becomes, for instance, 1.5×10¹⁸ cm⁻³.

The n-type dopant thus doped within the barrier layer 15 and the cap layer 16 may compensate the acceptors inherently induced in those layers, 15 and 16, which may further reduce the leak current of the HEMT 2A. Moreover, because the n-type dopants may generate conductive carriers, namely, electrons, the HEMT 2A thus formed may reduce the sheet resistance of the channel and increase the maximum forward current (Ifₘₐₓ).

The sheet resistance and the maximum forward current of the channel, and the leak current were compared between three devices, one of which was formed in the buffer layer 13 thereof without adding the nitrogen (N₂), namely a comparable example; while, another one was formed by adding the nitrogen (N₂), namely, the embodiment of the present invention, and the last one was formed by supplying n-type dopants, namely the first modification of the embodiment. The results of the sheet resistance, the maximum forward current, and the leak current were, 530 Ω/□, 760 Ω/□, and 5.0×10⁻⁵ A/mm, respectively, for the comparable example; 530 Ω/□, 760 Ω/□, and 9.0×10⁻⁶ A/mm, respectively, for the present embodiment; and 520 Ω/□, 780 mA/mm, and 1.0×10⁻⁵ A/mm, respectively, for the first modification. Thus, the process of the present embodiment may reduce the leak current and increase the maximum forward current without increasing the sheet resistance.

The buffer layer 13 inherently shows an acceptor density of 1.0×10¹⁶ cm⁻³ or less when the buffer layer 13 is grown without adding the nitrogen (N₂). It could be hard to compensate the acceptors with such a faint amount by supplying the n-type dopants, Excess doping of the n-type impurities results in the degradation of the drift performance of the device due to the capture and de-capture of carries by the n-type impurities. The addition of the nitrogen (N₂) of the present embodiment is not the compensation of the acceptor by the addition of the nitrogen (N₂), but the suppression of the generation of the acceptors by the sublimation of the nitrogen from the surface of the grown layer.

### Second Embodiment

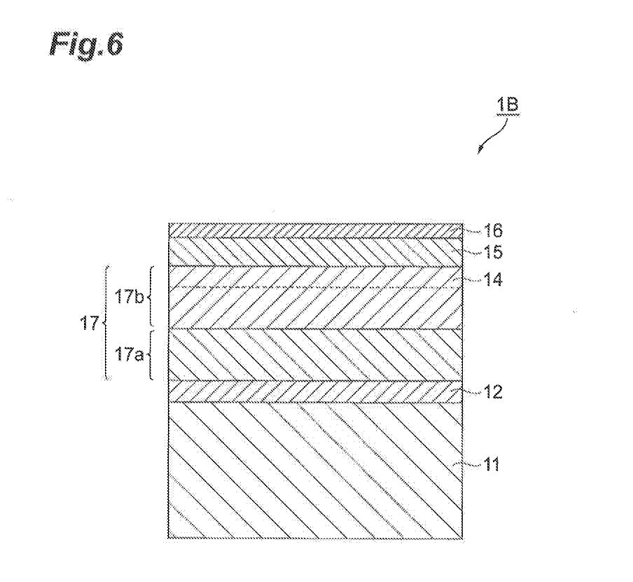

The embodiment thus described provides the buffer layer 13 formed by a unique GaN layer, However, the epitaxial substrate 1A and/or the HEMT 2A may provide a composite buffer layer. For instance, as illustrated in FIG. 6, the epitaxial substrate 1B includes, instead of the unique buffer layer 13, a buffer layer 17 comprising a lower layer 17a and an upper layer 17b. The lower layer 17a may be made of AlGaN with a thickness of 0.5 μm, where the composition of aluminum (Al) with respect to gallium (Ga) may be 0.05. The upper layer 17b may be made of GaN with a thickness of 0.5 μm. The composite buffer layer 17 of the present modification may further reduce the leak current because of wider bandgap energy of the AlGaN lower layer compared with bandgap energy of the GaN lower layer.

While particular examples of the present invention have been described herein for purposes of illustration, many modifications and changes not restricted to those above described will become apparent to those skilled in the art, For instance, the HEMT 2A formed on the epitaxial substrate may remove the cap layer. Also, the buffer layer and the barrier layer may take various combinations not restricted to those described above. Accordingly, the appended claims are intended to encompass all such modifications and changes as fall within the true spirit and scope of this invention.

What is claimed is:

1. A process of forming an epitaxial substrate made of nitride semiconductor materials, comprising steps of:
growing a buffer layer made of nitride semiconductor material on a substrate by a metal organized chemical vapor deposition (MOCVD) technique as supplying ammonia (NH₃) as a source material for nitrogen (N); and
growing a barrier layer made of nitride semiconductor material on the buffer layer,
wherein the step of growing the buffer layer includes a step of supplying a nitrogen gas (N₂) with the ammonia (NH₃).

2. The process of claim 1,
wherein the step of growing the buffer layer is carried out under a growth temperature higher than 1000° C.

3. The process of claim 1,
wherein the MOCVD technique provides a reaction chamber in which the epitaxial substrate is formed, the reaction chamber providing a supply line for supplying the ammonia (NH₃) into the reaction chamber, and
wherein the step of growing the buffer layer includes a step of supplying the nitrogen gas (N₂) commonly through the supply line for the ammonia (NH₃).

4. The process of claim 1,
wherein the step of growing the buffer layer includes a step of setting a flow rate of the nitrogen gas (N₂) against the ammonia (NH₃) to be 10 to 100 ppm.

5. The process of claim 1,
wherein the step of growing the barrier layer includes a step of supplying the ammonia (NH₃) added with the nitrogen gas (N₂).

6. The process of claim 1,
wherein the step of growing the barrier layer includes a step of supplying a dopant gas for an n-type impurity in the barrier layer,

7. The process of claim 6,
wherein the step of growing the barrier layer includes a step of supplying silane (SiH₄) as a source material for the n-type impurity in the barrier layer.

8. The process of claim 1,
wherein the step of growing the buffer layer includes a step of further supplying a hydrogen gas (H₂) as a carrier gas for group HI elements.

9. The process of claim 1,
further comprising a step of growing a seed layer made of aluminum nitride (AlN) before the step of growing the buffer layer.

10. The process of claim 9,
wherein the step of growing the buffer layer includes a step of sequentially growing an aluminum-gallium-nitride (AlGaN) layer and a gallium-nitride (GaN) layer on the seed layer as supplying the ammonia (NH₃) as the source material for the nitrogen (N) with the nitrogen gas (N₂).

11. The process of claim 10,
wherein the step of growing the AlGaN layer in the buffer layer includes a step of growing the AlGaN layer with an aluminum (Al) composition of 0.05 with, respect to a gallium composition.

12. The process of claim 10,
wherein the step of growing the AlGaN layer and the GaN layer in the buffer layer includes a step of growing the AlGaN layer with a thickness of 0.5 μm and the GaN layer with a thickness of 0.5 μm.

13. The process of claim 1,
wherein the step of growing the buffer layer includes a step of growing gallium nitride (GaN) by a thickness of 0.5 to 2.0 μm.

14. The process of claim 13,
wherein the step of growing the buffer layer includes a step of growing the GaN layer by a thickness of around 1.0 μm.

15. The process of claim 1,
wherein the step of growing the barrier layer includes a step of growing aluminum-gallium-nitride (AlGaN) layer by a thickness of 10 to 50 nm with an aluminum (Al) composition of 0.2 with respect to a gallium (Ga) composition.

16. A method to form a high electron mobility transistor (HEMT), comprising steps of
forming an epitaxial substrate by sequentially growing a seed layer, a buffer layer, and a barrier layer by a metal organic chemical. vapor deposition (MOCVD) technique on a substrate, where the seed layer, the buffer layer, and the barrier layer are made of nitride. semiconductor materials; and
forming electrodes of a gate, a source, and a drain on the epitaxial substrate,
wherein at least the step of growing the buffer layer includes a step of supplying ammonia (NH₃) within a reaction chamber of the MOCVD technique mixed with a nitrogen gas (N₂).

17. The method of claim 16,
wherein the step of growing the buffer layer includes a step of supplying the nitrogen gas (N₂) within the reaction chamber through a supply line for the ammonia (NH₃).

18. The method of claim 17,
wherein the step of growing the barrier layer includes a step of supplying the nitrogen gas (N₂) with the reaction chamber through the supply line for the ammonia (NH₃).

19. The method of claim 17,
wherein the step of growing the barrier layer includes a step of supplying a dopant gas for an n-type impurity in the barrier layer.

20. The method of claim 16,
wherein the step of growing the buffer layer includes a step of sequentially growing a lower layer made of aluminum-gallium-nitride (AlGaN) and an upper layer made of gallium nitride (GaN) on the seed layer, where the AlGaN layer having an aluminum (Al) composition of 0.05 with respect to a gallium (Ga) composition.
